(19) United States
(12) Patent Application Publication
(10) Pub. No.: US 2017/0182523 A1
(43) Pub. Date: Jun. 29, 2017

(54) TREATMENT METHOD AND DEVICE USING A SUPERCRITICAL FLUID AND INJECTION OF ADDITIVE

(71) Applicant: DFD - DENSE FLUID DEGREASING, Le Bourget du Lac (FR)

(72) Inventors: Alain CHAVRIER, Bourgoin Jallieu (FR); Sébastien FAYETTE, Bourdeau (FR)

(21) Appl. No.: 15/313,162

(22) PCT Filed: May 28, 2015
(86) PCT No.: PCT/EP2015/061885

§ 371 Date: Nov. 22, 2016

(30) Foreign Application Priority Data
May 28, 2014 (FR) 1454890

(51) Int. Cl. B08B 7/00; H01L 21/67; B08B 3/08; H01L 21/02; B08B 3/02; B08B 3/04

(52) U.S. Cl. CPC B08B 7/0021; B08B 3/02; B08B 3/045; B08B 3/08; H01L 21/02101; H01L 21/67051; B08B 3/04

(57) ABSTRACT

A treatment device using a supercritical fluid comprises: a chamber (14) for receiving the parts to be treated, provided with an opening and closing door (15), means (6, 8) for supplying a supercritical fluid to the chamber (14), comprising first fluid storage means (6) and means (10,12) for bringing the fluid to the supercritical state, second storage means (30), for storing a second fluid, such as an additive, for example a solvent, means (34, 36, 38) for injecting into the chamber the second fluid stored in the second storage means (30), at atmospheric pressure or at a pressure substantially close to atmospheric pressure, or together with the supercritical fluid, after the door is closed and the parts to be cleaned are loaded into the chamber.

### TECHNICAL FIELD AND STATE OF THE PRIOR ART

The invention relates to treatment techniques, in particular extraction, for example cleaning, of parts or objects by implementation of a dense fluid, for example supercritical, notably carbon dioxide.

This cleaning technique is known from the document WO 02/32593.

A known device for implementing such a technique will be described with reference to the schematic representation of FIG. 1.

This device is supplied with a liquefied gas, which comes for example from a reserve, or cylinder, 2, in which it is maintained at a temperature of, for example, −20° C.

This reserve 2 makes it possible to supply, via a pump 3 or a filling compressor and a valve 6₁, a storage chamber 6, which stores both the gas in gaseous form and liquefied gas. In this chamber, the gas is heated by the heating means 7, which is going to make it possible to increase its temperature, for example to 20° C., and to bring it to a pressure of several tens of bars, for example around 60 bars.

Liquefied gas, withdrawn from this chamber 6 using a valve 6₃, may then be taken, by the means 8, under thermodynamic conditions enabling it to be used as a cleaning fluid in the cleaning chamber 14, also called autoclave and of which the inlet is controlled by a valve 14₁. In particular, the means 8 may comprise pumping means 10 and heating means 12. In the case where the fluid is CO₂, the pump 10 makes it possible to bring the fluid coming from the reserve 6 to a pressure greater than 73.85 bars, and the heating means 12 make it possible to bring the temperature of the fluid to a value greater than 31° C., these conditions assuring the fluid is in a supercritical state.

In the autoclave, the fluid may be used in accordance with the teaching of the document WO 02/32193. The autoclave 14 is provided with a door 15 that is going to make it possible to introduce therein the parts to be cleaned. After the door is closed, the fluid is introduced under pressure, at for example 120 bars, and the parts are cleaned by the action of the fluid.

In the course of a cleaning cycle, the fluid is then evacuated, depressurised by depressurisation means 16 (mainly comprising a regulation valve 16₂ and a valve 16₁), then sent to means 18 forming a separator, which are going to make it possible to separate the gas from particles and dirt that have been recovered during the cleaning and with which the gas is loaded.

The gas thus treated may then be conveyed to liquefaction means 19, then again stored in liquid form in the chamber 6.

At the start of a cleaning cycle, after introduction of the parts to be cleaned into the autoclave 14 then closing the door 15 thereof, but before the start of the cleaning cycle itself, gas is introduced into the autoclave, at a pressure of the order of several bars. This gas comes from the chamber 6. To this end, a valve 6₂ is arranged on a path defined by a conduit 9 that connects an upper part of the chamber 6 and a point arranged between the pump 10 and the heating means 12. This valve and this conduit make it possible to withdraw gas, in gaseous form. This gas is then heated by the means 12.

This step makes it possible, when the dense fluid gas is then introduced, under pressure, from the means 8, to avoid that it is under conditions that can lead to the formation of a block of ice (this is the phenomenon, in the case of carbon dioxide, of formation of dry ice), which is to be avoided because this ice may be very difficult to eliminate rapidly.

Furthermore, as described in the document WO 02/32593, it is interesting to use, in combination with the dense fluid implemented, a liquid additive such as a co-solvent for example. The injection of this additive takes place in general under pressure, from a storage reservoir 30 of this additive. This reservoir may be arranged as indicated in FIG. 1, a high pressure pump 301 being arranged at the outlet of the reservoir with a view to injecting it into the corresponding conduit, in which the fluid circulates at high pressure.

Such a high pressure pump 301 is costly. Furthermore, such a pump requires maintenance, and is susceptible to breakdowns. In other words, it also has a cost due to its maintenance.

The problem is thus posed of finding a novel method for injecting a solvent into a dense fluid cleaning machine.

More generally, it is sought to be able to inject, in an economic manner, an additive, for example a solvent, into a dense fluid treatment machine.

### DESCRIPTION OF THE INVENTION

The invention aims to resolve these problems.

According to the invention a treatment device using dense fluid, for example a fluid in the supercritical state, comprises:

a) a chamber for receiving the parts to be treated, provided with an opening and closing door (or, more generally, means for establishing fluid communication, then isolating, the inside of the chamber with respect to the outer atmosphere),

b) means for supplying said dense fluid to said chamber, for example in the supercritical state, comprising first fluid storage means and means for bringing the fluid to the dense state, for example supercritical,

c) second storage means for storing a second fluid, such as an additive, for example a solvent, also called co-solvent,

d) means for injecting into the chamber the second fluid stored in the second storage means, at atmospheric pressure or at a pressure substantially close to atmospheric pressure, or together with the dense fluid, after loading the parts to be treated then stopping or closing the fluid communication between the inside of the chamber and the outer atmosphere.

Here and throughout the remainder of the document, the expression “establishing fluid communication”, applying to 2 volumes, signifies that a fluid can circulate, or flow, from one volume to the other. The means for establishing fluid communication are also means for interrupting this fluid communication, that is to say stopping any possibility of flow of fluid from one volume to the other.

The expression “at atmospheric pressure or substantially close to atmospheric pressure” signifies in general a pressure that may be comprised between 1 and 2 bars or between 1 and 5 bars. Said injection means may comprise a low pressure pump. Or instead they enable an injection by gravity.

In a variant, said injection means may comprise:
means, forming an intermediate reservoir arranged on the path of the fluid that comes out of said second storage means, between the latter and said chamber,
means for filling this intermediate reservoir from said second storage means,
and means for injecting, into said chamber, or to the inlet thereof, at least some of the contents of said means forming an intermediate reservoir.

According to this embodiment, the device may moreover comprise:
means for introducing, into said means forming an intermediate reservoir, a pressurised fluid, in the dense state, for example supercritical,
and means for introducing, into said chamber, or to the inlet thereof, a mixture of this pressurised fluid and the second fluid.

Said means forming an intermediate reservoir may comprise:
a first orifice for introducing therein the second fluid and injecting it into the chamber,
a second orifice, different to the first, for introducing therein pressurised fluid.

Or instead, said means forming an intermediate reservoir may comprise:
a first orifice for introducing therein the second fluid and the pressurised fluid,
a second orifice, different to the first, for injecting said mixture of pressurised fluid and the second fluid into the chamber.

The invention thus also relates to a treatment device using a supercritical fluid, comprising:

a) a chamber for receiving the parts to be treated, provided with means for establishing fluid communication between the inside of the chamber and the external atmosphere,

b) means for supplying supercritical fluid to said chamber comprising first storage means of said fluid and means for bringing this fluid to the supercritical state,

c) second storage means, for storing a second fluid, such as an additive,

d) means for injecting into the chamber the second fluid stored in the second storage means, together with the supercritical fluid, after loading the parts to be cleaned and closing the means for establishing fluid communication between the inside of the chamber and the outer atmosphere, these injection means comprising:

d1)—means, forming an intermediate reservoir, comprising:
a first orifice, for introducing therein, on the one hand, the second fluid at atmospheric pressure or at a pressure substantially close to atmospheric pressure and, on the other hand, the pressurised fluid, in the supercritical state,
a second orifice, different to the first, for injecting or for introducing a mixture of pressurised fluid and the second fluid into the chamber or to the inlet thereof.

Preferably, said means forming an intermediate reservoir can store a quantity of second fluid independent of the quantity of fluid contained in the second storage means.

According to a particular embodiment, said means for introducing, into said chamber, or to the inlet thereof, a mixture of this pressurised fluid and the second fluid comprises a check valve that only opens if the pressure is greater than a given set pressure.

The invention also relates to a treatment method using a dense fluid, for example supercritical, implementing a device according to the invention, in particular of the type as described above.

The invention also relates to a treatment method using dense fluid, potentially supercritical, comprising:

a) the introduction of at least one first part to be treated, into a chamber, provided with an opening and closing door, (or, more generally, means for establishing fluid communication, then isolating, the chamber with respect to the outer atmosphere), then closing this door (or, more generally, stopping or closing the communication between the chamber and the outer atmosphere);

b) the injection of an additive, for example a solvent, into said chamber at a pressure substantially equal to, or close to, atmospheric pressure,

c) then, the supply of said chamber with dense fluid and the treatment of said part.

The additive may be injected into the chamber at low pressure, for example using a low pressure pump or instead uniquely by gravity.

The additive may be firstly injected into an intermediate reservoir, then introduced into the chamber.

The invention also relates to a treatment method using a dense fluid, for example supercritical, comprising, in this order:

a) the introduction of at least one first part to be treated, into a chamber, provided with an opening and closing door, (or, more generally, means for establishing fluid communication, then isolating, the inside of the chamber with respect to the outer atmosphere), then closing this door (or, more generally, stopping or closing the fluid communication between the chamber and the outer atmosphere),

b) then the injection into said chamber of a mixture of at least one additive and a flow of dense fluid, for example supercritical, and the treatment of said part by this mixture.

According to an embodiment, the additive may be firstly injected into an intermediate reservoir then introduced into the chamber. A dense fluid, under pressure, for example in the supercritical state, may be introduced into the intermediate reservoir, after injection of the additive into the latter, a mixture of this pressurised fluid and the additive then being introduced into said chamber, or to the inlet thereof.

The introduction of the mixture into the chamber makes it possible to introduce therein the additive at the same time as the dense fluid, which makes it possible to dispense with the implementation of a high pressure pump, and which offers, moreover, a time saving compared to introduction of the additive before the implementation of the treatment method.

A pressurised fluid, in the supercritical state, may be introduced into the intermediate reservoir, after injection of additive into the latter, a mixture of this pressurised fluid and additive then being introduced into said chamber, or to the inlet thereof.

It is possible to introduce into said means forming an intermediate reservoir:
the second fluid via a first orifice and said mixture is injected, into the chamber, via this same orifice,
the pressurised fluid via a second orifice, different to the first.

Or instead, it is possible to:
introduce, into said means forming an intermediate reservoir, the second fluid and the pressurised fluid, via a same first orifice,
then inject said mixture of pressurised fluid and the second fluid into the chamber via a second orifice, different to the first.

Said means forming an intermediate reservoir may store a quantity of second fluid independent of the quantity of fluid contained in the second storage means.

In the method according to the invention, the part to be treated may be at least in part made of a metal material, and/or a metal alloy, and/or a ceramic material, and/or a semiconductor material, and/or a textile material and/or a natural material, that is to say not initially treated by human beings.

The treatment may be an extraction treatment, for example cleaning or degreasing, or debinding, or sterilisation. The treatment may also be a method of impregnation or input of product transported by the dense fluid, for example supercritical, within the material to be treated for example a colorant, or a chemical.

The invention also relates to a computer programme comprising instructions for implementing a method according to the invention, in particular as described above.

The invention also relates to a data support, which can be read by a computer system, comprising data, in coded form, for implementing a method according to the invention, in particular as described above.

The invention also relates to a software product comprising programme data support means, capable of being read by a computer system, making it possible to implement a method according to the invention, in particular as described above.

### BRIEF DESCRIPTION OF THE DRAWINGS

FIG. 1 is a diagram of a treatment machine using a supercritical fluid, of known type,

FIGS. 2-5A represent various configurations of another embodiment of a treatment machine using a supercritical fluid, according to the invention,

FIG. 6 is a schematic representation of means for controlling a machine according to the invention.

### DETAILED DESCRIPTION OF PARTICULAR EMBODIMENTS

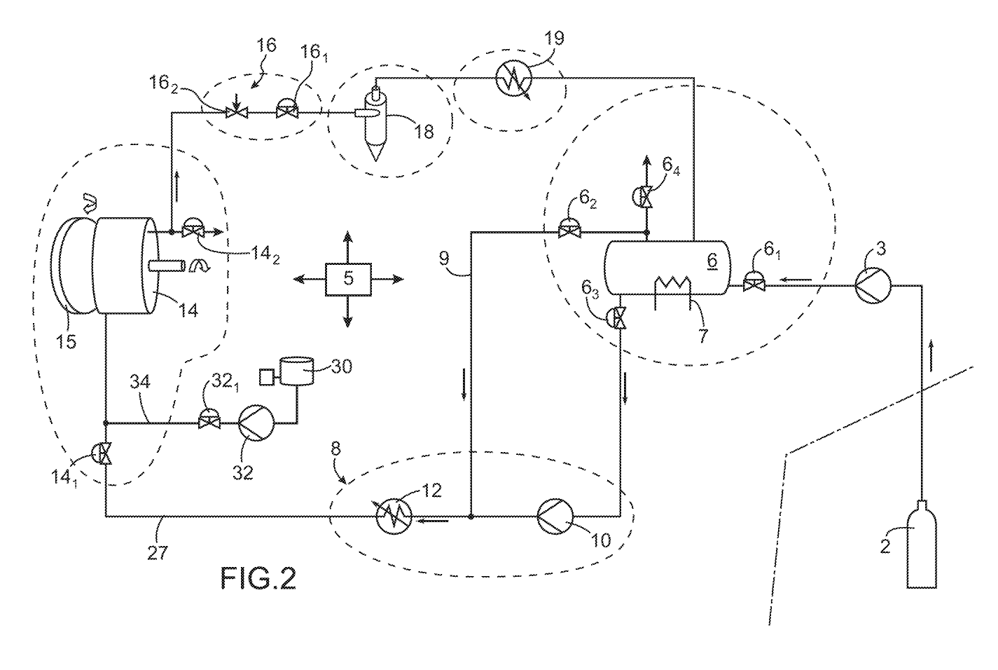

In FIG. 2 is represented an example of embodiment of a machine according to the invention.

In particular, this machine comprises first storage means 6 (or storage chamber, called main storage chamber of the system), provided for storing liquefied gas, at several tens of bars, for example 60 bars. This chamber may be provided with means for measuring the temperature and/or the pressure and/or the level of liquid that it contains. It may be supplied by a reserve 2, which has for example a vat shape (which contains gas at, for example, −20° C. and 20 bars), to which the device may be connected. This reserve is placed in communication with the storage chamber 6 via the valve 6₁, and a filling pump 3 or a compressor.

The initial filling of this chamber may be carried out in the following manner. Liquefied gas is introduced therein by pumping and opening of the inlet valve 6₁, at the temperature of the reserve 2, for example 20 bars and −20° C. In the course of the treatment, this chamber could, moreover, be supplied by gas recycled from the treatment chamber 14.

The heating means 7 then make it possible to increase the temperature and pressure conditions in this chamber 6, for example, for CO₂, to +20° C. and 60 bars, or, more generally, to a temperature comprised between 15° C. and 30° C., and a pressure comprised between 50 bars and 90 bars.

An autoclave 14, or treatment chamber, receives the parts to be treated. This chamber is provided with a door 15, through which the parts may be introduced into the chamber, then, after treatment, extracted from the chamber. It may also be provided with a vent, or a conduit forming a vent, and a valve 14₂.

Means for, potentially, making this autoclave move, as well as means for receiving baskets that are going to contain the parts to be cleaned, are described in the document WO 02/32593.

Means 8, comprising for example a pump 10 and heating means 12 make it possible to convey the fluid, withdrawn from the chamber 6, under thermodynamic conditions enabling it to be used in the treatment chamber 14. In the case where the fluid is CO₂, the pump 10 makes it possible to bring the fluid from the reserve 6 to a pressure greater than 73.85 bars, and the heating means 12 make it possible to bring the temperature of the fluid to a value greater than 31° C., these conditions then assuring that the fluid is in a so-called supercritical state. The fluid circulates in the conduit 27, the valve 14₁ opening access of the flow of supercritical fluid to the autoclave 14.

Means 16 (in this example: a valve 16₁ and a regulation valve 16₂) make it possible to depressurise the gas at the outlet of the autoclave 14.

Means 18, forming a separator, make it possible to separate the gas from extracted impurities or products that it transports and which result from a preceding or underway treatment operation.

The whole of these means make it possible to carry out a treatment cycle, that is to say a series of steps, which mainly include:

a) the loading of the parts into the autoclave 14,

b) the closing of the door 15 and means 14₂ (or, more generally, the stopping or the closing of the establishment of fluid communication, that is to say the impossibility of fluid exchange between the inside of the chamber and the outer atmosphere),

c) the treatment of the parts by action of the dense fluid on the parts to be treated; this step is carried out at high pressure P₀, for example greater than 100 bars, again for example around 120 bars for supercritical CO₂,

d) the reduction of the pressure in the chamber, from P₀ to a value P₁, substantially less than P₀; P₁ is for example of the order of several tens of bars, or even comprised between 50 bars and 90 bars, or instead between 60 and 70 bars.

e) the opening of the door (or, more generally, the establishment of fluid communication between the inside of the chamber and the outer atmosphere) and the unloading of the parts; the internal volume of the autoclave is then at atmospheric pressure.

It is sought to introduce an additive to the dense fluid, in order to carry out a specific treatment on the parts.

As explained in the patent application WO 02/32593, for example for a cleaning treatment, the addition of a co-solvent to the dense fluid, under pressure, makes it possible to obtain improved extraction of contaminating organic compounds, pollutants, in other words undesirable compounds, from the parts to be cleaned.

This co-solvent may be selected, for example, from among water, aqueous solutions, alcohols, for example 1 to 5 C aliphatic alcohols, such as ethanol, methanol, butanol, ketones, such as acetone, and mixtures thereof.

Among aqueous solutions may be cited detergents solutions such as anionic and/or cationic surfactants, solutions of complexing agents, chelating agents, buffer solutions, for example phosphate and/or hydrogen phosphate, etc.; antioxidant solutions, such as ascorbic acid, to stabilise the material.

Other types of additives may be added, instead of the solvent, or in combination therewith:
an additive of fragrance type (added for example at the end of the cycle),
an impregnation product, for example a paint and/or a tanning product (for example chromium VI or a plant tannin), and/or an oil, and/or a hydrophobic product.

Compared to the structure that has been described above, the embodiment of FIG. 2 comprises, moreover, second storage means 30, or reservoir, containing, or intended to contain, an additive to inject into the chamber before the start, or at the start, of a treatment cycle, after loading of the parts of the material to be treated into this chamber and closing the door 15 and means 14₂ (or, more generally, stopping or closing the establishment of fluid communication between the inside of the chamber and the outer atmosphere, that is to say the establishment of a state in which it is impossible to achieve any fluid exchange between the inside of the chamber and the outer atmosphere). This additive is in general stored in the means 30 in liquid form. It is injected at atmospheric pressure, or close to atmospheric pressure (comprised between 1 and 2 bars or between 1 and 5 bars), considerably less than the working pressure. This reservoir 30 may be provided with means for measuring the pressure and/or the temperature and/or the level and/or the volume of the liquid or the fluid that it contains.

In the structure represented in FIG. 2, the reservoir 30 is connected, via a valve 32₁ and a conduit 34, to the inlet of the autoclave 14. Potentially, a low pressure pump 32 may be arranged at the outlet of the reservoir 30, this pump making it possible to inject the fluid at atmospheric pressure or at a pressure comprised between 1 and 2 bars. Thus, the additive may be injected into the autoclave 14 at a pressure close to atmospheric pressure. This pump may not be necessary if the reservoir 30 is above the autoclave 14, the flow taking place just by action of gravity. This injection takes place after closing the door 15 and before injection of the dense treatment fluid.

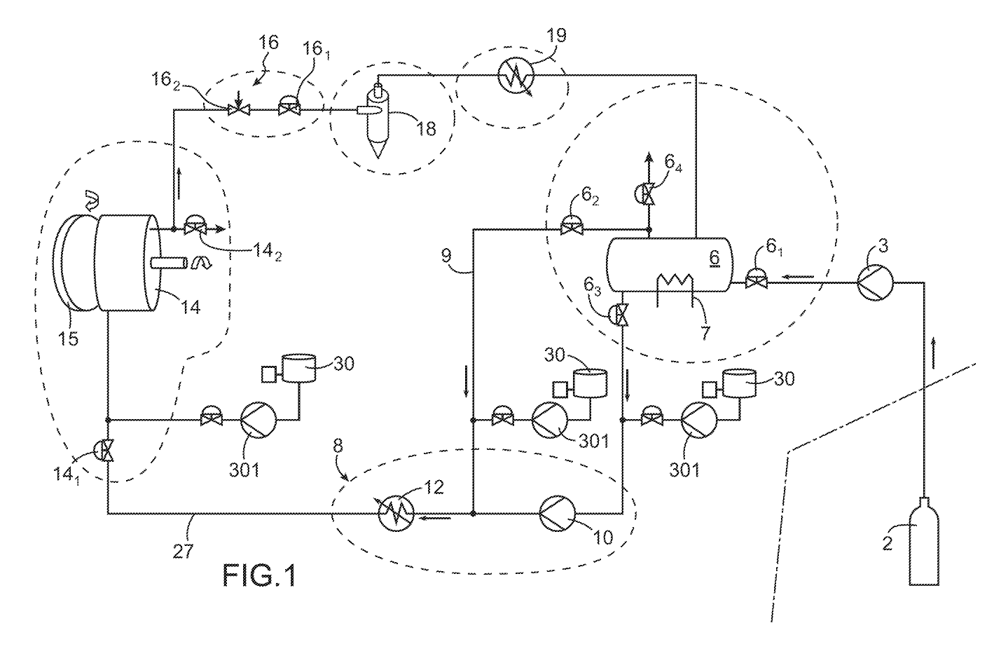

As already explained above with reference to FIG. 1, it is known to inject an additive into the autoclave 14, together with the pressurised dense fluid. To do so, it is necessary to implement a high pressure pump 301. For example, in the structure of FIG. 1, in the case where solvent is injected upstream of the exchanger 12, mixed with gas withdrawn from the chamber 6, it is necessary to increase the pressure of the solvent until it reaches the pressure of the withdrawn gas.

The injection, according to the invention, of an additive at atmospheric pressure or at a pressure substantially close to atmospheric pressure makes it possible to dispense with, for the injection of additive, the use of a high pressure pump, which is costly, in particular in terms of maintenance.

The operation of this machine is then identical to that which has been described above.

The sequence of steps that take place at the start of a treatment cycle is for example the following:

a—loading the parts and closing the door and the means 14₂ (or, more generally, stopping or closing the establishment of fluid communication between the inside of the chamber and the outer atmosphere, that is to say the establishment of a state in which it is impossible to achieve any fluid exchange between the inside of the chamber and the outer atmosphere),

b—injection of the additive at atmospheric pressure or close to atmospheric pressure,

c—then injection of gas into the autoclave, to bring it to a pressure of around 5 to 15 bars, in order to avoid the formation of dry ice.

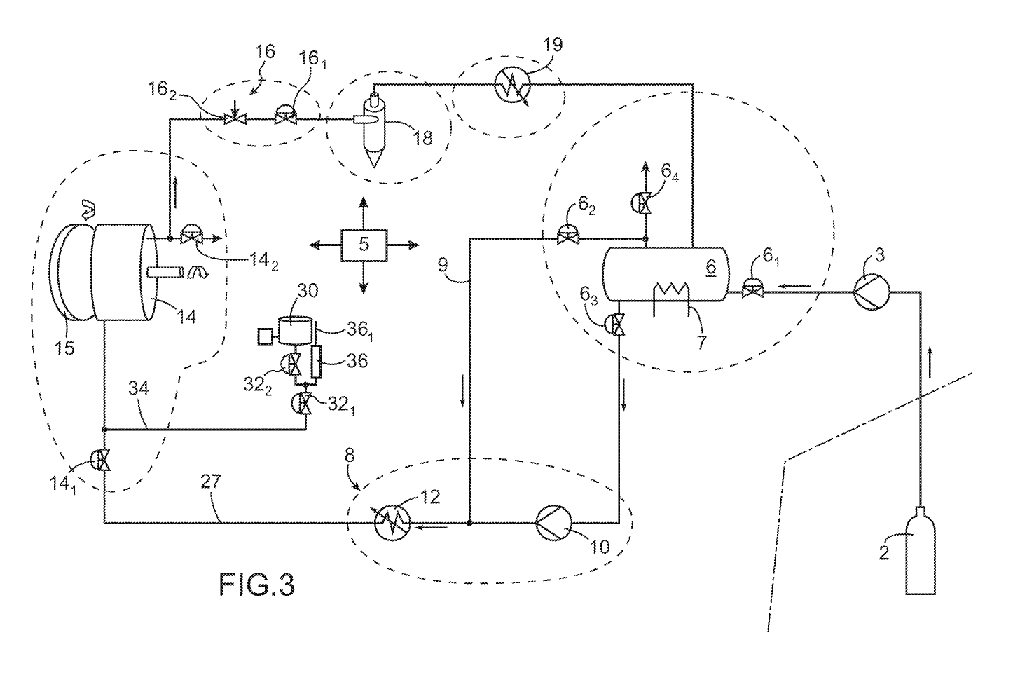

A variant, with a view to injection of additive at a pressure identical to, or substantially close to, atmospheric pressure, is illustrated in FIG. 3. In this figure, references identical to those of FIGS. 1-2 designate identical or similar elements. This device moreover comprises a cartridge 36 in which a quantity of additive to inject into the autoclave is going to be able to be stored temporarily, at atmospheric pressure, or close to atmospheric pressure, in liquid form, after having been withdrawn from the reservoir 30.

Preferably, in order not to use a pump, the cartridge 36 is situated below the reservoir 30 and above the autoclave 14.

In this device, the outlet of the reservoir 30 of additive may be controlled by a set of valves 32₁, 32₂, that are going to make it possible:
first of all, by opening the valve 32₂, after closing the valve 32₁, to store temporarily the additive in the cartridge 36, of known volume. The liquid goes from the reservoir 30 to the cartridge 36 through simple action of gravity. The cartridge 36 is extended by a conduit 36₁ rising higher than the reservoir 30 and of small section making it possible to have in the volume of the cartridge 36 a quantity approximately independent of the filling of the reserve 30; the valve 32₂ may then be closed,
then, by opening the valve 32₁, the additive, stored in the cartridge 36, may be injected, via conduit 34, to the inlet of the autoclave 14.

This injection of additive thus takes place uniquely by action of gravity, without use of a pump or energy other than actuation of the valves.

The sequence of steps at the start of the treatment cycle may be identical to the sequence of steps a-c that have been described above.

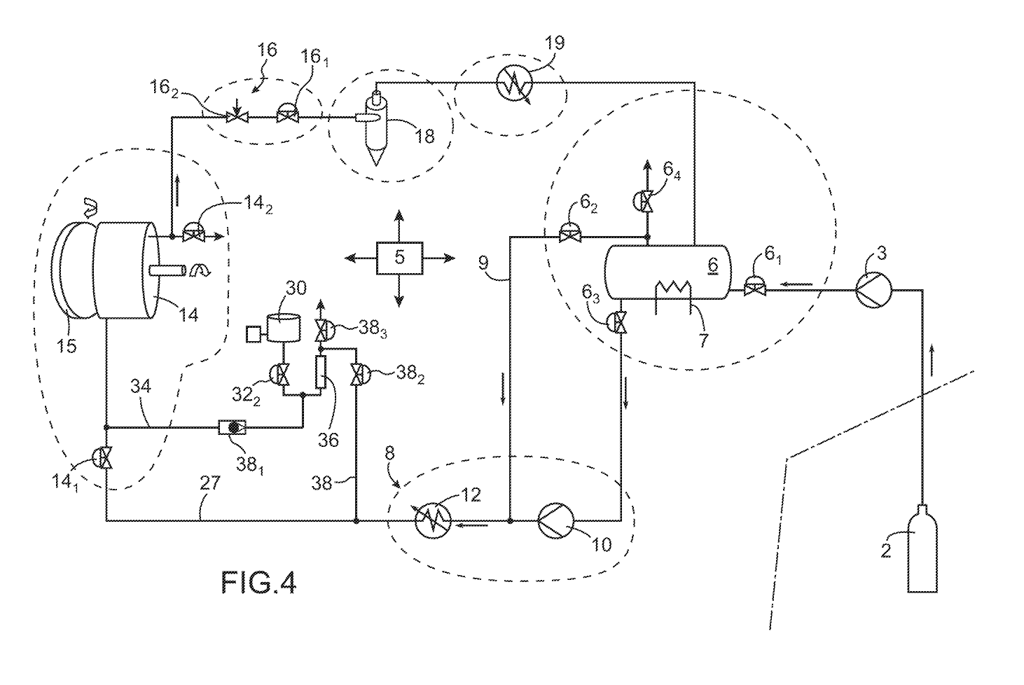

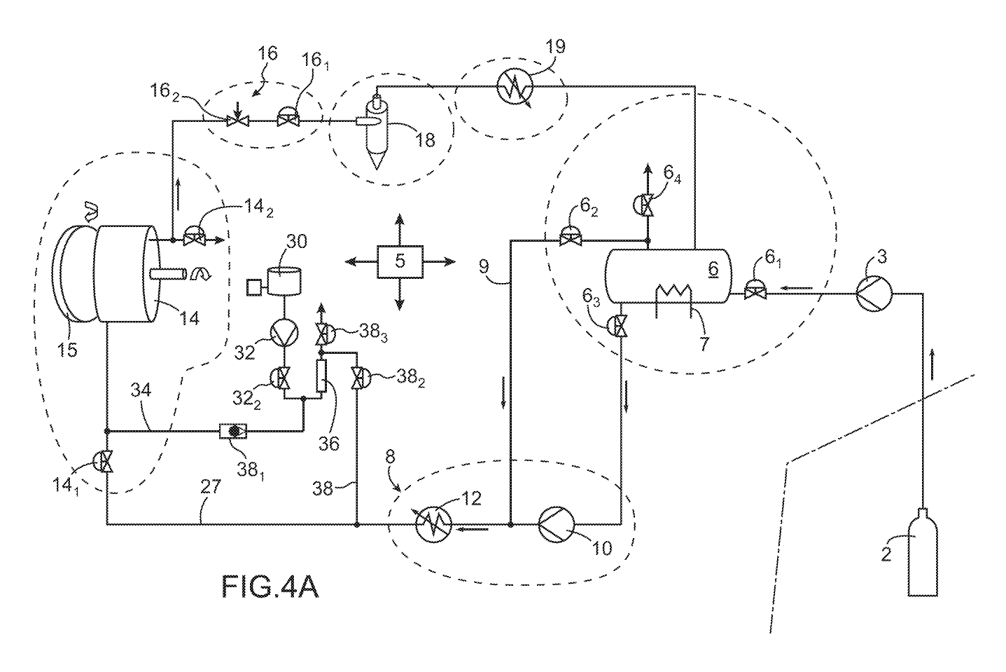

Yet another variant, with a view to an injection of an additive to the inlet of the autoclave 14, is illustrated in FIG. 4. In this figure, identical references to those of FIGS. 1-3 designate identical or similar elements. Here again, the cartridge 36 is going to make it possible to store temporarily a quantity of additive to inject into the autoclave, after withdrawal from the reservoir 30. This time, the volume of the cartridge 36 may be placed in communication with the outlet of the means 8, in order to send, into the cartridge 36, a quantity of dense fluid, potentially supercritical, which is going to make it possible to sweep out the cartridge and to introduce the additive to the inlet of the autoclave 14.

In a more precise manner, in this device, the outlet of the reservoir 30 of additive is controlled by the valve 32₂.

First of all, by opening this same valve 32₂, additive may be stored temporarily in the cartridge 36, of known volume. The storage pressure in the cartridge is atmospheric pressure or is close to atmospheric pressure. According to a variant illustrated in FIG. 4A, a pump 32 is used (for example a low pressure metering pump) situated between the reserve 30 and the valve 32₂ to only fill the cartridge 36 with the desired quantity of additive. This quantity then becomes adjustable. This low pressure pump 32, arranged at the outlet of the reservoir 30, makes it possible to inject the additive into the cartridge 36 at atmospheric pressure or at a pressure comprised between 1 and 2 bars. This pump 32 may in particular be used when the action of gravity cannot be used (in the case of a too viscous additive, for example).

Potentially, means 38₁, forming a check valve, may be provided downstream of the cartridge 36, on the route 34. These means 38₁, which can only open under a given pressure (to which the check valve is calibrated), greater than the pressure at which the additive is stored in the cartridge 36, then assure the closing of the route 34 for the additive. A conduit 38 makes it possible to withdraw dense fluid at the outlet of the means 8. If the dense fluid is carbon dioxide, it is then in the supercritical state. A valve 38₂ is arranged on this conduit 38, and is going to make it possible to control the introduction of this fluid into the cartridge 36. When this valve is open, the fluid, arriving under high pressure, sweeps out the cartridge 36, taking along with it the additive, at a sufficient pressure to open the check valve 38₁ (when it is present). The latter could be replaced by a valve synchronised with the opening of the valve 38₂

In the embodiment that has just been explained, the additive enters into the cartridge 36, from the reservoir 30, and exits therefrom, to be injected into the autoclave 14, via a same orifice, which may be situated at a first end of the cartridge 36. This is different to it, which may be situated at a second end of the cartridge 36, opposite to the first end, through which the dense fluid enters into the cartridge 36. It is for example arranged in a manner opposite to that through which the dense fluid enters into the cartridge.

The sequence of steps that take place at the start of a cleaning cycle is for example the following:

a′—loading of the parts and closing the door and the means 14₂ (or, more generally, stopping or closing the establishment of fluid communication between the inside of the chamber and the outer atmosphere, that is to say the establishment of a state in which it is impossible to achieve any fluid exchange between the inside of the chamber and the outer atmosphere),

b′—then injection of gas into the autoclave, to bring it to a pressure of around 5 to 15 bars, in order to avoid the formation of dry ice.

In the course of the treatment cycle, at the desired moment, the opening of the valve 38₂ and the closing of the valve 14₁ enable the dense fluid to pass through the cartridge 36 and carry along the additive.

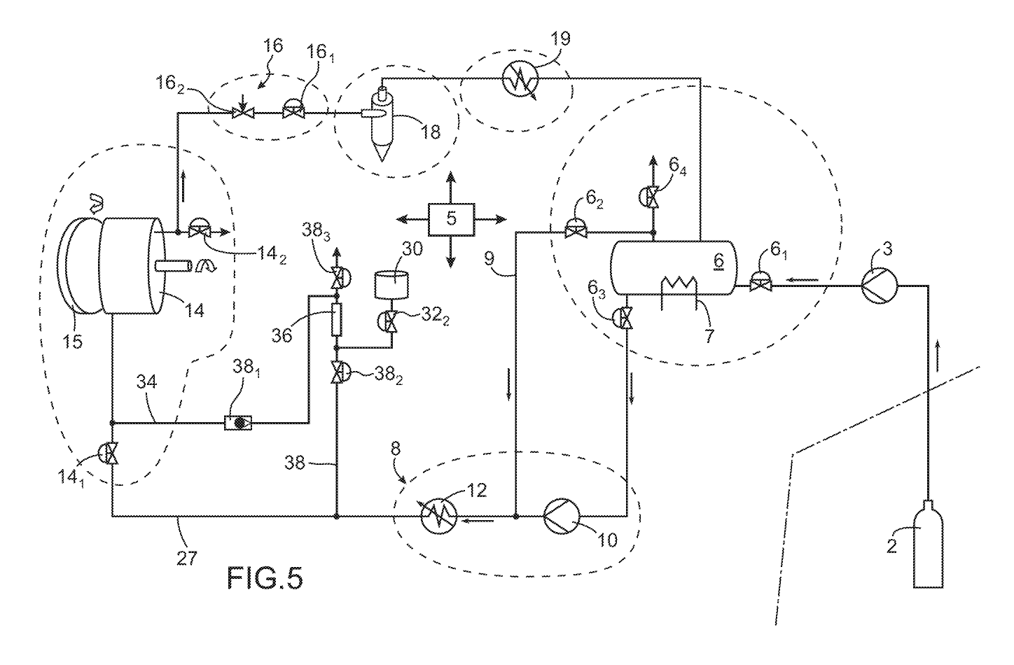

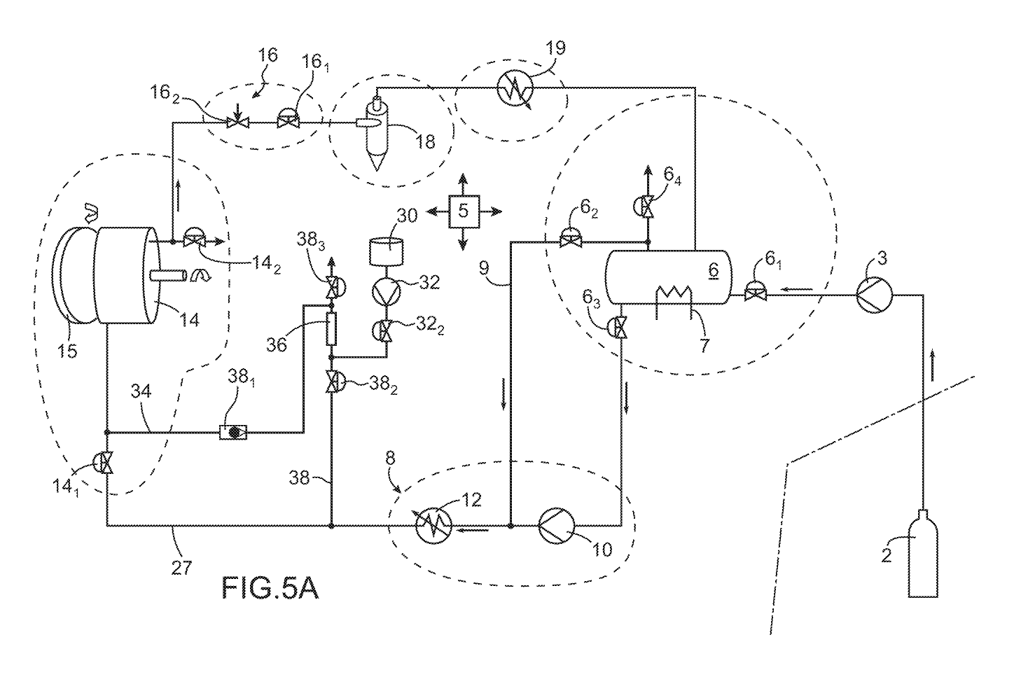

Yet another variant, with a view to injection of additive to the inlet of the autoclave 14, is illustrated in FIG. 5. In this figure, references identical to those of FIG. 4 designate identical or similar elements.

Here again, the volume of the cartridge 36 may be placed in communication with the outlet of the means 8, in order to send, into the cartridge 36, a quantity of dense fluid, potentially supercritical, which is going to make it possible to sweep out the cartridge and to introduce the additive to the inlet of the autoclave 14.

More precisely, in this device, the outlet of the additive reservoir 30 may be controlled by the valve 32₂.

First of all, by opening this same valve 32₂, the additive may be stored temporarily in the cartridge 36, of known volume.

The conduit 38 makes it possible to withdraw dense fluid at the outlet of the means 8. But, here, the dense fluid enters into the cartridge 36 through the bottom and comes out through the top while bubbling through the additive, which makes it possible to carry along the additive progressively by dissolution; the dense fluid is going to dissolve the additive on its passage and to carry along a part thereof. There is thus an action of the additive extended over time and the dense fluid is not saturated with additive in one go.

Depending on the density of the additive compared to the dense fluid, a mounting according to FIG. 4 or according to FIG. 5 could be used.

The sequence of steps at the start of the cleaning cycle may be identical to the sequence of steps a′-b′ that has been described above.

In the two embodiments of FIGS. 4 and 5, the additive is injected with the dense fluid, under pressure, it may thus be injected when so desired during the cleaning cycle, which constitutes an advantageous gain, in time and operating flexibility, compared to the embodiments that have been described previously. According to a variant illustrated in FIG. 5A, a pump 32 is used, for example a low pressure dosing pump, situated between the reserve 30 and the valve 32₂ to only fill the cartridge 36 with the desired quantity of additive. This quantity then becomes adjustable. This low pressure pump 32, arranged at the outlet of the reservoir 30, makes it possible to inject the additive, into the cartridge 36, at atmospheric pressure or at a pressure comprised between 1 and 2 bars.

In the embodiments of FIGS. 3-5A, the cartridge 36 may be provided with means for heating it or thermostatically controlling it (or maintaining it at constant temperature), in order that, or such that, the dense fluid is not liquefied. This cartridge is thus provided with means that make it possible to maintain the dense fluid that it contains at a temperature such that it is not in liquid form or that it does not condense.

In the embodiments of FIGS. 3-5A, the cartridge 36 may be equipped with level measuring means so as to adjust the quantity of additive. There is closing of the valve 32₂ when the desired quantity is reached. This may also be carried out by a measurement of the flow rate coming out of the reservoir 30 or instead by measuring the variation of level in the reservoir 30.

Whatever the envisaged embodiment, apart from the above means, a device according to the invention may comprise means 5, of electronic and/or computer type, for controlling and regulating the operation of each of the components of the machine, notably the pumps and the valves, according to a programmed sequence of steps.

These controller forming means 5 may comprise circuits, which make it possible to send to each of the components of the machine instructions and/or voltages enabling it to be run according to a predefined sequence. In particular, these means are going to make it possible to implement a cleaning preparation cycle and/or a cleaning cycle as described above, and notably to adjust the steps of transfer of gas between the means 2 and 6 on the one hand, and the storage means 20 on the other hand. More precisely, these means are going to control the opening or closing durations of the valves 32₁, 32₂, 38₁, 38₂, 38₃, but also other valves of the system, and the operation, notably, of the pump 10, and the means 12.

This assembly 5 may moreover potentially receive signals corresponding to measurements carried out using one or more pressure sensors, for example arranged to measure the pressure in the autoclave 14, or in the storage means 20, and can process them and use them for the control of one or more components of the machine.

This controller assembly 5 may communicate with a user interface to inform a user of the status of the machine, in particular its operating cycle.

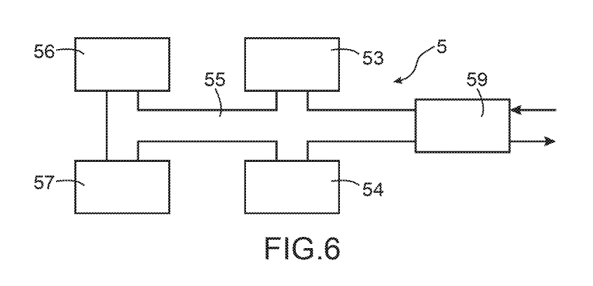

An example of embodiment of these means 5 is described below in a more precise manner with reference to FIG. 6.

In this example, these means comprise means 53 for memorising instructions relative to the processing of data, for example to carry out a method of the type described above.

According to an example of embodiment, the controller 5 comprises a central unit, which itself includes a microprocessor 56, a set of non-volatile memories and RAM 57, peripheral circuits, all of these elements being coupled to a bus 55. Data may be stored in the memory zones, notably data for implementing a method according to the present invention or for controlling a machine according to the present invention. Means 59 are going to make it possible to manage the flow of input and output data, from other components of the machine, and in the direction thereof.

In a variant, this controller assembly 5 may be realised in the form of a FPGA (Field Programmable Gate Array) or an ASIC (Application Specific Integrated Circuit).

The means 54, which may comprise visualisation means, may potentially enable a user to interact with the operation of a machine according to the invention, for example by intervening on a particular step of an operating cycle.

A machine according to the invention, and a method for operating such a machine, as described above, makes it possible to achieve the saving of a high pressure pump such as one of the pumps 301 of FIG. 1.

This saving may be obtained:
either by injection of the additive at low pressure, as for example explained above with reference to FIGS. 2 and 3,
or by injection of the additive at high pressure using the dense fluid, during treatment, as for example explained above with reference to FIGS. 4 and 5.

The invention has been described above within the scope of the implementation of a pressurised dense fluid, notably carbon dioxide in the supercritical state. It may apply to other fluids, in particular nitrogen or oxygen, under conditions enabling them to be in the supercritical state (for oxygen: beyond −119° C. and 50 bars; for nitrogen: beyond −147° C. and 34 bars)

In a variant, another fluid may be implemented, for example a fluid selected from among methane, ethanol, propane, nitrogen protoxide, a fluorinated gas, ammonia, alcohol, ethanol, isopropanol, water.

The invention has been described above for a cleaning method.

But other methods may be implemented using a device or a method according to the invention, the suitable fluid being used in the dense state, or even supercritical state. For each of the different examples cited below, CO₂ may be used.

In all cases, the fluid, whether dense or super-critical, bathes the parts to be treated. The contact, more or less long, between the latter and the fluid brings about the sought after treatment.

This is the case, for example, of a debinding method or an extraction method (cleaning being a particular case of extraction).

A debinding method makes it possible to extract a binder from a part made of an alloy, for example from a powder such as a powder assembled in a paraffin, and/or to extract any binder adapted to the manufacture of the alloy.

Again for example, a method for extracting one or more natural substances may be implemented in particular in the pharmaceuticals or food processing industry.

An extraction method, or instead degreasing, may also be implemented for treating natural wool, in order to extract suint therefrom.

The invention also makes it possible to implement a sterilisation method (for example in the food-processing or medical field), at low temperature, based on the penetrability of the gas, at high pressure, which is going to be able to penetrate into the material to be treated and to neutralise, or to kill, infectious agents.

The invention may also be used in methods of impregnation or input of product transported by the supercritical fluid within the material to be treated.

More generally, any type of part may be treated by a method according to the invention.

The materials, which can be treated by a method according to the invention, are generally solid materials, for example:
metals,
metal alloys, potentially plated, such as aluminium, titanium, steel, stainless steel, copper, brass, and any other alloy, or plated metal,
ceramic materials, polymer materials, powders, notably powders of the materials cited above,
textile materials, natural or synthetic, or instead leather,
rectification sludges, stemming for example from a bar turning method.

The treated parts may be, for example:
parts from the aeronautics, or automobile, industry
clock making and/or micromechanical parts,
electric or electronic connectors,
components made of semiconductor materials from the microelectronics industry,
medical or surgical apparatus or tools, etc.
clothes, or natural materials used in the textile industry, for example wool, or leather.

What is claimed is:

1-17. (canceled)

18. Treatment device using a supercritical fluid comprising:
a) a main chamber for receiving the parts to be treated, provided with a door for establishing fluid communication between the inside of the chamber and the outer atmosphere,
b) a first circuit for supplying a supercritical fluid to said chamber, comprising a fluid storage chamber,
c) a first reservoir, for storing a second fluid, such as an additive,
d) a second circuit to inject into the main chamber the second fluid stored in said reservoir, at atmospheric pressure or at a pressure substantially close to atmospheric pressure, after the parts to be cleaned are loaded in the main chamber and the door for establishing fluid communication between the inside of the main chamber and the outer atmosphere is closed.

19. Device according to claim 18, said second circuit comprising a low pressure pump or instead enabling an injection by gravity.

20. Device according to claim 18, further comprising:
a second intermediate reservoir arranged on the path of the fluid that comes out of said first reservoir, between the latter and said main chamber,
a circuit for filling this second intermediate reservoir from said first reservoir,
and at least a valve for injecting or introducing, into said main chamber, or the inlet thereof, at least some of the contents of said second intermediate reservoir.

21. Device according to claim 20, said second intermediate reservoir being able to store a quantity of second fluid independent of the quantity of fluid contained in the first reservoir.

22. Device according to claim 20, said second intermediate reservoir being able to maintain a fluid in gaseous form.

23. Device according to claim 20, said valve for introducing, into said main chamber, or to the inlet thereof, a mixture of this pressurised fluid and the second fluid, comprising a check valve that only opens if the pressure is greater than a given set pressure.

24. Treatment device using a supercritical fluid, comprising:
a) a main chamber for receiving the parts to be treated, provided with a door to establish fluid communication between the inside of the chamber and the outer atmosphere,
b) a first circuit for supplying said main chamber with fluid, in the supercritical state, comprising a fluid storage chamber,
c) a first reservoir for storing a second fluid, such as an additive,
d) a second circuit for injecting into the main chamber, with the supercritical fluid, after loading the parts to be cleaned and closing the door, the second fluid from said first reservoir, said second circuit comprising:
d1)—a second intermediate reservoir arranged on the path of the fluid that comes out of said first reservoir, between the latter and said main chamber, said second intermediate reservoir comprising:
a first orifice, for introducing therein, on the one hand, the second fluid at atmospheric pressure or at a pressure substantially close to atmospheric pressure and, on the other hand, the pressurised fluid, in the supercritical state,
a second orifice, different to the first, for injecting or for introducing a mixture of pressurised fluid and the second fluid into the chamber or at the inlet thereof.

25. Device according to claim 24, said second intermediate reservoir being able to store a quantity of second fluid independent of the quantity of fluid contained in the first reservoir.

26. Device according to claim 24, said intermediate reservoir being able to maintain a fluid in gaseous form.

27. Device according to claim 24, said valve for introducing, into said main chamber, or to the inlet thereof, a mixture of this pressurised fluid and the second fluid, comprising a check valve that only opens if the pressure is greater than a given set pressure.

28. Method of cleaning using a supercritical fluid comprising, in this order:
a) the introduction of at least one first part to be cleaned into a chamber, provided with a door for establishing fluid communication between the inside of the chamber and the outer atmosphere, then closing said door,
b) then the injection into said chamber, at atmospheric pressure or at a pressure substantially close to atmospheric pressure, of at least one co-solvent,
c) then the supply of said chamber with supercritical fluid and the cleaning of said part.

29. Method according to claim 28, the co-solvent being injected into the chamber using a low pressure pump or instead uniquely by gravity.

30. Method according to claim 28, the additive being firstly injected into an intermediate reservoir, then introduced into the chamber.

31. Method according to claim 28, the additive being:
a solvent, for example selected from among water, aqueous solutions, alcohols, for example 1 to 5 C aliphatic alcohols, such as ethanol, methanol, butanol, ketones, such as acetone, and mixtures thereof,
and/or a fragrance,
and/or an impregnation product, for example a paint and/or a tanning product, and/or an oil, and/or a hydrophobic product.

32. Method according to claim 28, the dense fluid being nitrogen or oxygen, or a fluid selected from among methane, ethanol, propane, nitrogen protoxide, a fluorinated gas, ammonia, alcohol, ethanol, isopropanol, water.

33. Treatment method using a supercritical fluid comprising, in this order:
a) the introduction of at least one first part to be cleaned, into a chamber, provided with a door for establishing fluid communication between the inside of the chamber and the outer atmosphere, then stopping or closing the communication between the inside of the chamber and the outer atmosphere,
b) then:
the introduction, into an intermediate reservoir, via a same first orifice, of an additive or a second fluid, at atmospheric pressure or at a pressure substantially close to atmospheric pressure, then pressurised fluid, in the supercritical state,
the injection of a mixture of pressurised fluid, in the supercritical state, and the second fluid or the additive, into the chamber, or to the inlet thereof, via a second orifice, different to the first.

34. Method according to claim 33, said intermediate reservoir being arranged on the path of the fluid that comes out of another reservoir, between the latter and said main chamber, storing a quantity of second fluid independent of the quantity of fluid contained in said other reservoir.

35. Method according to claim 33, said intermediate reservoir being maintained at a temperature making it possible to maintain the second fluid in gaseous form.

36. Method according to claim 33, the additive being:
a solvent, for example selected from among water, aqueous solutions, alcohols, for example 1 to 5 C aliphatic alcohols, such as ethanol, methanol, butanol, ketones, such as acetone, and mixtures thereof,
and/or a fragrance,
and/or an impregnation product, for example a paint and/or a tanning product, and/or an oil, and/or a hydrophobic product.

37. Method according to claim 33, the dense fluid being nitrogen or oxygen, or a fluid selected from among methane, ethanol, propane, nitrogen protoxide, a fluorinated gas, ammonia, alcohol, ethanol, isopropanol, water.
